(19) United States
(12) Patent Application Publication
(10) Pub. No.: US 2024/0279543 A1
(43) Pub. Date: Aug. 22, 2024

(54) FLUORIDE FLUORESCENT BODY, METHOD FOR PRODUCING SAME, AND LIGHT EMISSION APPARATUS

(71) Applicant: NICHIA CORPORATION, Anan-shi (JP)

(72) Inventor: Tomokazu YOSHIDA, Anan-shi (JP)

(73) Assignee: NICHIA CORPORATION, Anan-shi (JP)

(21) Appl. No.: 18/258,737

(22) PCT Filed: Dec. 9, 2021
(86) PCT No.: PCT/JP2021/045352

§ 371 Date: Jun. 21, 2023

(30) Foreign Application Priority Data
Dec. 22, 2020 (JP) 2020-212532
Jul. 7, 2021 (JP) 2021-112539
Sep. 6, 2021 (JP) 2021-144746

(51) Int. Cl. C09K 11/64

(52) U.S. Cl. CPC C09K 11/645

(57) ABSTRACT

Provided is a red light emitting phosphor having a high luminance. The fluoride phosphor has a first composition which includes an alkali metal containing K, Si, Al, Mn, and F. In the first composition, when a total number of moles of the alkali metal is 2: a total number of moles of Si, Al, and Mn is 0.9 to or more and 1.1 or less; a number of moles of Al is more than 0 but and 0.1 or less; a number of moles of Mn is more than 0 but and 0.2 or less; and the a number of moles of F is 5.9 to 6.1. The fluoride phosphor has a crystal structure of cubic system, and a lattice constant of not less than 0.8138 nm.

### TECHNICAL FIELD

The present disclosure relates to a fluoride phosphor, a method of producing the same, and a light emitting device.

### BACKGROUND ART

Various light emitting devices using a combination of a light emitting element and a phosphor have been developed and utilized in a wide range of fields, including illumination, vehicle-mounted lighting, displays, and liquid crystal backlights. For example, a phosphor used in a light emitting device for liquid crystal backlight application is required to have a high color purity, i.e. an emission peak with a narrow half-value width. As a red light emitting phosphor having an emission peak with a narrow half-value width, Japanese Laid-Open Patent Publication No. 2012-224536 discloses, for example, a fluoride phosphor having a composition represented by K₂SiF₆: Mn.

### SUMMARY OF INVENTION

### Technical Problem

A phosphor used in a light emitting device is also required to have an improved luminance in addition to an emission peak with a narrow half-value width. For example, the fluoride phosphor disclosed in Japanese Laid-Open Patent Publication No. 2012-224536 has room for improvement in terms of luminance. Therefore, an object of one embodiment of the present disclosure is to provide a red light emitting phosphor having a high luminance.

### Solution to Problem

A first embodiment is a fluoride phosphor that has a first composition which includes an alkali metal containing K, Si, Al, Mn, and F. In the first composition, when a total number of moles of the alkali metal is 2: a total number of moles of Si, Al, and Mn is 0.9 or more and 1.1 or less; a number of moles of Al is more than 0 and 0.1 or less; a number of moles of Mn is more than 0 and 0.2 or less; and a number of moles of F is 5.9 or more and 6.1 or less. The fluoride phosphor has a crystal structure of cubic system, and a lattice constant of not less than 0.8138 nm.

A second embodiment is a light emitting device that includes: a first light emitting material containing the fluoride phosphor of the first embodiment; and a light emitting element having an emission peak wavelength in a wavelength range of 380 nm to 485 nm.

A third embodiment is a method of producing a fluoride phosphor, the method including:
providing first fluoride particles having a second composition which includes an alkali metal containing K, Si, Mn, and F, and in which, when a total number of moles of the alkali metal is 2: a total number of moles of Si and Mn is 0.9 or more and 1.1 or less; a number of moles of Mn is more than 0 and 0.2 or less; and the number of moles of F is 5.9 or more and 6.1 or less;
providing second fluoride particles having a third composition which includes an alkali metal containing K, Al, and F, and in which, when the number of moles of Al is 1: a total number of moles of the alkali metal is 2 or more and 3 or less; and a number of moles of F is 5 or more and 6 or less; and
obtaining a first heat-treated product by performing a first heat treatment of a mixture of the first fluoride particles and the second fluoride particles in an inert gas atmosphere in a temperature range of 600° C. or higher and 780° C. or lower.

### Advantageous Effects of Invention

According to one embodiment of the present disclosure, a red light emitting phosphor having a high luminance may be provided.

### BRIEF DESCRIPTION OF DRAWINGS

FIG. 1 is a flow chart that illustrates the process order of a method of producing a fluoride phosphor.

FIG. 2 is a schematic cross-sectional view that illustrates an exemplary light emitting device containing a fluoride phosphor.

FIG. 3 shows infrared absorption spectra of fluoride phosphors.

FIG. 4 is an exemplary scanning electron microscope (SEM) image of the fluoride phosphor according to Comparative Example 1.

FIG. 5 is an exemplary SEM image of the fluoride phosphor according to Example 3.

FIG. 6 shows infrared absorption spectra of the fluoride phosphors according to Example 3 and Reference Example.

FIG. 7 shows infrared absorption spectra of first and second fluoride particles.

### DESCRIPTION OF EMBODIMENTS

The term “step” used herein encompasses not only a discrete step but also a step that cannot be clearly distinguished from other steps, as long as the intended purpose of the step is achieved. When there are plural substances that correspond to a component of a composition, an indicated amount of the component contained in the composition means, unless otherwise specified, a total amount of the plural substances existing in the composition. Further, upper limit and lower limit values that are described for a numerical range in the present specification can be arbitrarily selected and combined. In the present specification, the relationships between color names and chromaticity coordinates, the relationships between wavelength ranges of light and color names of monochromatic light, and the like conform to JIS Z8110. A “half-value width” of a phosphor or light emitting material means a wavelength width in which the emission intensity is 50% relative to the maximum emission intensity in an emission spectrum of the phosphor or light emitting material (full-width at half maximum; FWHM). A “median diameter” of a phosphor refers to a volume-based median diameter which is a particle size corresponding to a cumulative volume of 50% from the small diameter side in a volume-based particle size distribution. The particle size distribution of a phosphor is measured by a laser diffraction method using a laser diffraction-type particle size distribution analyzer. Embodiments of the present invention will now be described in detail. It is noted here, however, that the below-described embodiments are merely examples of a fluoride phosphor, a method of producing the same, and a light emitting device that embody the technical idea of the present invention, and the present invention is not limited to the below-described fluoride phosphor, method of producing the same, and light emitting device.

### Fluoride Phosphor

The fluoride phosphor has a first composition which includes an alkali metal containing potassium (K), silicon (Si), aluminum (Al), manganese (Mn), and fluorine (F). This fluoride phosphor has a crystal structure of cubic system, and a lattice constant of not less than 0.8138 nm. In the first composition, when a total number of moles of the alkali metal is 2: a total number of moles of Si, Al, and Mn is 0.9 to 1.1; the number of moles of Al is more than 0 and 0.1 or less; the number of moles of Mn is more than 0 and 0.2 or less; and the number of moles of F is 5.9 to 6.1. The Mn contained in the fluoride phosphor may contain a tetravalent Mn ion. The fluoride phosphor may be produced by, for example, the below-described method of producing a fluoride phosphor.

The fluoride phosphor may exhibit a higher luminance by having a composition which includes Si and Al at a specific content ratio of Al, as well as a crystal structure of cubic system in which the lattice constant is a prescribed value or more. The reason for this is believed to be, for example, as follows. It is believed that, as a result of partial substitution of Si constituting the crystal structure of the fluoride phosphor with Al, F defects in the crystal structure are compensated, and the crystal structure is thereby stabilized. In addition, as a result of partial substitution of Si contained in the crystal structure of the fluoride phosphor with Al, the fluoride phosphor exhibits a lattice constant of a prescribed value or more. Further, since the fluoride phosphor contains Al in the crystal structure, the fluoride phosphor exhibits, for example, a peak derived from Al—F bond in an infrared absorption spectrum.

In the first composition of the fluoride phosphor, a ratio of the total number of moles of Si, Al, and Mn may be, for example, 0.9 to 1.1, and it is preferably 0.95 to 1.05, or 0.97 to 1.03, with respect to a total of 2 moles of the alkali metal included in the composition. In addition, a ratio of the number of moles of Al with respect to a total of 2 moles of the alkali metal may be, for example, more than 0 and 0.1 or less, and it is preferably more than 0 and 0.03 or less, 0.002 to 0.02, or 0.003 to 0.015. Further, a ratio of the number of moles of Mn with respect to a total of 2 moles of the alkali metal may be, for example, more than 0 and 0.2 or less, and it is preferably 0.005 to 0.15, 0.01 to 0.12, or 0.015 to 0.1. Still further, a ratio of the number of moles of F with respect to a total of 2 moles of the alkali metal may be, for example, 5.9 to 6.1, and it is preferably 5.92 to 6.05, or 5.95 to 6.025. In the first composition, a ratio of the number of moles of Si with respect to a total of 2 moles of the alkali metal may be, for example, 0.7 to 1.1, and it is preferably 0.8 to 1.03, 0.85 to 1.01, or 0.92 or more and less than 0.95. In the first composition, a ratio of the number of moles of Al with respect to the number of moles of Si may be, for example, 0.001 to 0.14, and it is preferably 0.002 to 0.04, or 0.003 to 0.015.

Moreover, the ratio of the total number of moles of Si, Al, and Mn with respect to a total of 2 moles of the alkali metal may be preferably 0.95 or more, or 0.97 or more, but preferably 1.05 or less, or 1.03 or less. The ratio of the number of moles of Al with respect to a total of 2 moles of the alkali metal may be preferably 0.002 or more, or 0.003 or more, and preferably 0.03 or less, 0.02 or less, or 0.015 or less. The ratio of the number of moles of Mn with respect to a total of 2 moles of the alkali metal may be preferably 0.005 or more, 0.01 or more, or 0.015 or more, and preferably 0.15 or less, 0.12 or less, or 0.1 or less. The ratio of the number of moles of F with respect to a total of 2 moles of the alkali metal may be preferably 5.92 or more, or 5.95 or more, and preferably 6.05 or less, or 6.025 or less. The ratio of the number of moles of Si with respect to a total of 2 moles of the alkali metal may be preferably 0.8 or more, 0.85 or more, or 0.92 or more, and preferably 1.03 or less, 1.01 or less, or less than 0.95. The ratio of the number of moles of Al with respect to the number of moles of Si may be preferably 0.002 or more, or 0.003 or more, and preferably 0.04 or less, or 0.015 or less.

The fluoride phosphor may have a composition represented by the following Formula (I) as the first composition:

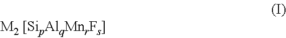

In Formula (I), M represents an alkali metal and may contain at least K. Mn may be a tetravalent Mn ion. Further, p, q, r, and s may satisfy, for example, 0.9≤p+q+r≤1.1, 0<q≤0.1, 0<r≤0.2, and 5.9≤s≤6.1. Preferably, p, q, r, and s may satisfy: 0.95≤p+q+r≤1.05, or 0.97≤p+q+r≤1.03; 0<q≤0.03, 0.002≤q≤0.02, or 0.003≤q≤0.015; 0.005≤r≤0.15, 0.01≤r≤0.12, or 0.015≤r≤0.1; and 5.92≤s≤6.05, or 5.95≤s≤6.025.

Further, preferably, p, q, and r may satisfy: 0.95≤p+q+r, or 0.97≤p+q+r; and p+q+r≤1.05, or p+q+r≤1.03. Preferably, q may be: 0.002≤q, or 0.003≤q; and q≤0.03, q≤0.02, or q≤0.015. Preferably, r may be: 0.005≤r, 0.01≤r, or 0.015≤r; and r≤0.15, r≤0.12, or r≤0.1. Preferably, s may be: 5.92≤s, or 5.95≤s; and s≤6.05, or s≤6.025.

In the compositions of the fluoride phosphor and the below-described first and second fluoride particles, the alkali metal contains at least K, and may also contain at least one selected from the group consisting of lithium (Li), sodium (Na), rubidium (Rb), and cesium (Cs). A ratio of the number of moles of K with respect to a total number of moles of the alkali metal in the respective compositions may be, for example, 0.90 or more, and it is preferably 0.95 or more, or 0.97 or more. An upper limit of the ratio of the number of moles of K may be, for example, 1, or 0.995 or less. In the first composition, the alkali metal may be partially substituted with an ammonium ion (NH₄⁺). When the alkali metal is partially substituted with an ammonium ion, a ratio of the number of moles of ammonium ion with respect to a total number of moles of the alkali metal in the composition may be, for example, 0.10 or less, and it is preferably 0.05 or less, or 0.03 or less. A lower limit of the ratio of the number of moles of ammonium ion may be, for example, more than 0, preferably 0.005 or more.

The fluoride phosphor may contain a crystal structure of cubic system, and may also contain a crystal structure of other crystal system such as a hexagonal system in addition to the crystal structure of cubic system, or may substantially consist of the crystal structure of cubic system. The term “substantially” used herein means that the content ratio of a crystal structure other than the crystal structure of cubic system is less than 0.5%. When the fluoride phosphor contains a crystal structure of cubic system, the lattice constant thereof may be, for example, 0.8138 nm or more, preferably 0.8140 nm or more, 0.8141 nm or more, 0.8142 nm or more, or 0.8143 nm or more. An upper limit of the lattice constant may be, for example, 0.8150 nm or less, or 0.8148 nm or less. Whether or not the fluoride phosphor contains a crystal structure of cubic system, and the lattice constant thereof may be evaluated by measuring the X-ray diffraction pattern of the fluoride phosphor. The X-ray diffraction pattern is measured using, for example, CuKa radiation (λ=0.15418 nm, tube voltage=40 kV, tube current=40 mA) as an X-ray source.

The fluoride phosphor may have an absorption peak in a wavenumber range of, for example, 590 cm⁻¹ to 610 cm⁻¹, preferably 593 cm⁻¹ to 607 cm⁻¹, or 595 cm⁻¹ to 605 cm⁻¹, in an infrared absorption spectrum. The absorption peak in this prescribed wavenumber range is believed to be derived from, for example, Al—F bond in the crystal structure of cubic system. The infrared absorption spectrum is measured by, for example, an attenuated total reflection (ATR) method.

The fluoride phosphor may have irregularities, grooves, and the like on its particle surface. It is believed that the incorporation of Al by the fluoride phosphor into its crystal structure leads to a change in the crystal structure, causing irregularities, grooves, and the like to be formed on the particle surface. The state of the particle surface may be evaluated by, for example, measuring the angle of repose of a powder composed of the fluoride phosphor. The angle of repose of a powder composed of the fluoride phosphor may be, for example, 60° or smaller, preferably 55° or smaller, or 50° or smaller. A lower limit of the angle of repose may be, for example, 30° or larger. The angle of repose of the powder may be measured using, for example, a powder property measuring device (e.g., A.B.D powder property analyzer, manufactured by Tsutsui Scientific Instruments Co., Ltd.).

The state of the particle surface of the fluoride phosphor may also be evaluated by measuring, for example, the dispersity, the bulk density, or the like of a powder composed of the fluoride phosphor. In the fluoride phosphor having a prescribed dispersity or a prescribed bulk density, aggregation of a powder composed of the fluoride phosphor is inhibited, and this makes the handling of the powder easier at the time of producing a light emitting device, so that the workability in the production process of a light emitting device is improved. In addition, since the packing density of the fluoride phosphor in the resulting light emitting device may be increased, the luminous flux of the light emitting device is expected to be improved. The dispersity of a powder composed of the fluoride phosphor may be, for example, 2.0% or more, preferably 5.0% or more, 15% or more, or 20% or more. An upper limit of the dispersity may be, for example, 75% or less, 60% or less, or 50% or less. The dispersity of the powder may be measured using, for example, a powder property measuring device (e.g., A.B.D powder property analyzer, manufactured by Tsutsui Scientific Instruments Co., Ltd.). Specifically, a sample is dropped from a hopper onto a saucer for dispersity measurement, and the dispersity is calculated in percentage by subtracting the weight of the sample remaining on the saucer from the weight of the dropped sample, and dividing the thus obtained value by the weight of the dropped sample.

The bulk density of a powder composed of the fluoride phosphor may be, for example, 1.00 g· cm⁻³ or higher, preferably 1.05 g·cm⁻³ or higher, 1.10 g·cm⁻³ or higher, or 1.15 g·cm⁻³ or higher. An upper limit of the bulk density may be, for example, 1.50 g. cm⁻³ or lower, 1.40 g·cm⁻³ or lower, or 1.30 g·cm⁻³ or lower. The bulk density is measured by, for example, an ordinary measurement method using a graduated cylinder. The bulk density will now be described concretely. Generally, the bulk density of a powder is determined by measuring the volume of a powder sample having a known weight that is put into a graduated cylinder, by measuring the weight of a powder sample having a known volume that is put into a container through a volumeter, or by using a special measurement container.

As an example, a method of using a graduated cylinder will now be described. First, a sample is prepared in an amount sufficient for the measurement and, as required, this sample is passed through a sieve. Next, a required amount of the sample is put into a dry graduated cylinder having a certain volume. At this point, the upper surface of the sample is leveled as required. These operations are gently performed not to affect the physical properties of the sample. Subsequently, the volume is read to the smallest scale unit, and the weight of the sample per unit volume is calculated to determine the bulk density. The bulk density is preferably measured repeatedly, and the bulk density is more preferably measured plural times and determined as an arithmetic mean value of the thus measured values.

For example, from the standpoint of improvement in the luminance, the volume-based median diameter of the fluoride phosphor may be 10 μm to 90 μm, preferably 15 μm or more, or 20 μm or more, but preferably 70 μm or less, or 50 μm or less. As for the particle size distribution of the fluoride phosphor, for example, from the standpoint of improvement in the luminance, the fluoride phosphor may exhibit a single-peak particle size distribution, preferably a single-peak particle size distribution with a narrow distribution width.

The fluoride phosphor is, for example, a phosphor activated by tetravalent Mn, and may absorb light in a short wavelength region of visible light and emit a red light. An excitation light may be a light mainly in the blue region, and the peak wavelength of the excitation light may be in a wavelength range of, for example, 380 nm to 485 nm. In the emission spectrum of the fluoride phosphor, an emission peak wavelength may be in a wavelength range of, for example, 610 nm to 650 nm. In the emission spectrum of the fluoride phosphor, a half-value width may be, for example, 10 nm or less.

### Method of Producing Fluoride Phosphor

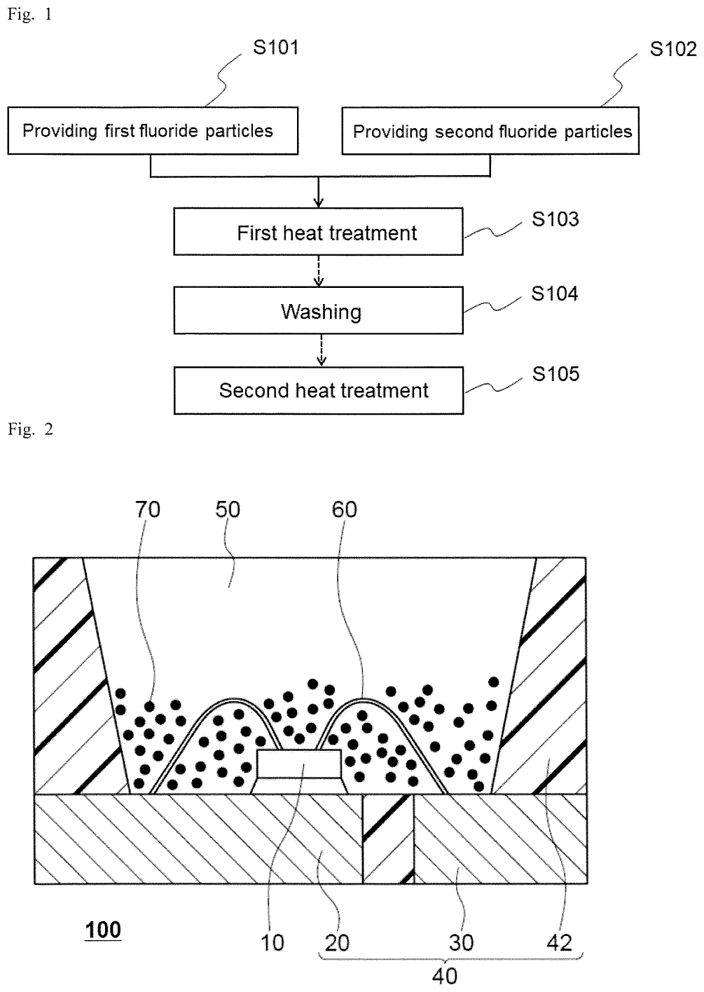

FIG. 1 is a flow chart that illustrates one example of the steps of a method of producing a fluoride phosphor. The method of producing a fluoride phosphor may include: (S101) providing of first fluoride particles; (S102) providing of second fluoride particles; and (S103) performing a first heat treatment. The (S101) providing of first fluoride particles and the (S102) providing of second fluoride particles may be performed one after the other, or may be performed simultaneously. The method of producing a fluoride phosphor may also include (S104) washing after the (S103) performing the first heat treatment, and may further include (S105) performing a second heat treatment after the (S104) washing.

The method of producing a fluoride phosphor includes: the first providing step of providing first fluoride particles; the second providing step of providing second fluoride particles; and the first heat treatment step of performing a first heat treatment of a mixture of the first fluoride particles and the second fluoride particles in an inert gas atmosphere in a temperature range of 600° C. to 780° C. so as to obtain a first heat-treated product. The first fluoride particles has a second composition which includes an alkali metal containing K, Si, Mn, and F. In the second composition, when a total number of moles of the alkali metal is 2: a total number of moles of Si and Mn is 0.9 to 1.1; a number of moles of Mn is more than 0 and 0.2 or less; and a number of moles of F is 5.9 to 6.1. The second fluoride particles has a third composition which includes an alkali metal containing K, Al, and F. In the third composition, when a number of moles of Al is 1: a total number of moles of the alkali metal is 2 to 3; and a number of moles of F is 5 to 6.

By heat-treating the mixture of the first fluoride particles containing Mn serving as an activation element and the second fluoride particles containing Al at a specific temperature, Al is introduced to the composition of the first fluoride particles, so that a fluoride phosphor exhibiting a high luminance may be produced. The reason for this is believed to be, for example, as follows. It is believed that, by heat-treating the mixture of the first fluoride particles and the second fluoride particles at a relatively high temperature, the second fluoride particles are incorporated into the first fluoride particles, and Si contained in the crystal structure of the first fluoride particles is partially substituted with Al, as a result of which F defects in the crystal structure of the resulting fluoride phosphor are compensated and the crystal structure is stabilized, whereby the luminance is improved.

### First Providing Step

In the first providing step, the first fluoride particles having the second composition are provided. The second composition may be a composition in which a ratio of a total number of moles of Si and Mn is 0.9 to 1.1, a ratio of the number of moles of Mn is higher than 0 and 0.2 or lower, and a ratio of the number of moles of F is 5.9 to 6.1, with respect to a total of 2 moles of the alkali metal. The ratio of a total number of moles of Si and Mn may be preferably 0.95 to 1.05, or 0.97 to 1.03. Further, the ratio of the number of moles of Mn may be preferably 0.005 to 0.15, 0.01 to 0.12, or 0.015 to 0.1. Moreover, the ratio of the number of moles of F may be preferably 5.95 to 6.05, or 5.97 to 6.03.

The first fluoride particles may have a composition represented by the following Formula (III) as the second composition:

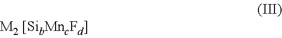

In Formula (III), M represents an alkali metal and may contain at least K. Mn may be a tetravalent Mn ion. Further, b, c, and d may satisfy 0.9≤b+c≤1.1, 0<c≤0.2, and 5.9≤d≤6.1. Preferably, b, c, and d may satisfy: 0.95<b+c≤1.05, or 0.97<b+c≤1.03; 0.005≤c≤0.15, 0.01≤c≤0.12, or 0.015≤c≤0.1; and 5.95≤d≤6.05, or 5.97≤d≤6.03.

For example, from the viewpoint of improvement in the luminance, the volume-based median diameter of the first fluoride particles may be 10 μm to 90 μm, preferably 15 μm to 70 μm, or 20 μm to 50 μm. As for the particle size distribution of the first fluoride particles, for example, from the standpoint of improvement in the luminance, the first fluoride particles may exhibit a single-peak particle size distribution, preferably a single-peak particle size distribution with a narrow distribution width. Specifically, in a volume-based particle size distribution where the particle size corresponding to a cumulative volume of 10% from the small side is defined as D10 while the particle size corresponding to a cumulative volume of 90% is defined as D90, a ratio of D90 to D10 (D90/D10) may be 3.0 or lower.

The first fluoride particles may be, for example, particles of a phosphor activated by tetravalent Mn ion, and may absorb light in a short wavelength region of visible light and emit a red light. An excitation light may be a light mainly in the blue region, and the peak wavelength of the excitation light may be in a wavelength range of, for example, 380 nm to 485 nm. In the emission spectrum of the first fluoride particles, an emission peak wavelength may be in a wavelength range of, for example, 610 nm to 650 nm. In the emission spectrum of the first fluoride particles, a half-value width may be, for example, 10 nm or less.

The first fluoride particles may be purchased, or produced by the below-described production method. Described below is a production method for a case where the alkali metal is potassium; however, the first fluoride particles may be produced in the same manner even in a case where the alkali metal contains an alkali metal other than potassium.

A method of producing the first fluoride particles includes the step of mixing, for example, a first solution which contains at least potassium ions and hydrogen fluoride, a second solution which contains at least tetravalent Mn ion-containing first complex ions and hydrogen fluoride, and a third solution which contains at least silicon and fluorine ion-containing second complex ions. By mixing the first, second, and third solutions, fluoride particles that have a desired composition and function as a phosphor may be produced by a simple method having excellent productivity.

The first solution contains at least potassium ions and hydrogen fluoride, and may also contain other components as required. The first solution is obtained as, for example, an aqueous hydrofluoric acid solution of a potassium ion-containing compound. Examples of the potassium ion-containing compound constituting the first solution include water-soluble compounds, such as potassium ion-containing halides, hydrofluorides, hydroxides, acetates, and carbonates. Specific examples thereof include water-soluble potassium salts, such as KF, KHF₂, KOH, KCl, KBr, KI, CH₃COOK, and K₂CO₃. Thereamong, KHF₂ is preferred because it may be dissolved without causing a reduction of the hydrogen fluoride concentration in the solution and has a high safety with low heat of dissolution. The potassium ion-containing compound constituting the first solution may be used singly, or two or more thereof may be used in combination.

A lower limit value of the hydrogen fluoride concentration in the first solution is usually 1% by mass or higher, preferably 3% by mass or higher, more preferably 5% by mass or higher. Meanwhile, an upper limit value of the hydrogen fluoride concentration in the first solution is usually 80% by mass or lower, preferably 75% by mass or lower, more preferably 70% by mass or lower. A lower limit value of the potassium ion concentration in the first solution is usually 1% by mass or higher, preferably 3% by mass or higher, more preferably 5% by mass or higher. Meanwhile, an upper limit value of the potassium ion concentration in the first solution is usually 30% by mass or lower, preferably 25% by mass or lower, more preferably 20% by mass or lower. When the potassium ion concentration is 5% by mass or higher, the yield of the first fluoride particles tends to be improved.

The second solution contains at least tetravalent Mn ion-containing first complex ions and hydrogen fluoride, and may also contain other components as required. The second solution is obtained as, for example, an aqueous hydrofluoric acid solution containing a tetravalent manganese source. This manganese source is, for example, a tetravalent Mn ion-containing compound. Specific examples of the manganese source constituting the second solution include K₂MnF₆, KMno₄, and K₂MnCl₆. Thereamong, K₂MnF₆ is preferred not only because it does not contain chlorine that tends to distort and destabilize the crystal lattice, but also because it may stably exist as an MnF₆ complex ion in hydrofluoric acid while maintaining an oxidation number (tetravalency) that allows activation. It is noted here that, among manganese sources, those containing a potassium ion may double as a potassium ion source contained in the first solution. The manganese source constituting the second solution may be used singly, or two or more thereof may be used in combination.

A lower limit value of the hydrogen fluoride concentration in the second solution is usually 1% by mass or higher, preferably 3% by mass or higher, more preferably 5% by mass or higher. Meanwhile, an upper limit value of the hydrogen fluoride concentration in the second solution is usually 80% by mass or lower, preferably 75% by mass or lower, more preferably 70% by mass or lower. A lower limit value of the first complex ion concentration in the second solution is usually 0.01% by mass or higher, preferably 0.03% by mass or higher, more preferably 0.05% by mass or higher. Meanwhile, an upper limit value of the first complex ion concentration in the second solution is usually 5% by mass or lower, preferably 3% by mass or lower, more preferably 2% by mass or lower.

The third solution contains at least second complex ions containing silicon and fluorine ion, and may also contain other components as required. The third solution is obtained as, for example, an aqueous solution containing a second complex ion source. This second complex ion source is preferably a compound which contains silicon and a fluoride ion and has excellent solubility in the solution. Specific examples of the second complex ion source include H₂SiF₆, Na₂SiF₆, (NH₄)₂SiF₆, Rb₂SiF₆, and CS₂SiF₆. Thereamong, H₂SiF₆ is preferred because it has a high solubility in water and contains no alkali metal element as an impurity. The second complex ion source constituting the third solution may be used singly, or two or more thereof may be used in combination.

A lower limit value of the second complex ion concentration in the third solution is usually 10% by mass or higher, preferably 15% by mass or higher, more preferably 20% by mass or higher. Meanwhile, an upper limit value of the second complex ion concentration in the third solution is usually 60% by mass or lower, preferably 55% by mass or lower, more preferably 50% by mass or lower. As a method of mixing the first, second, and

third solutions, for example, the second solution and the third solution may be added to the first solution with stirring and the resultant may be mixed, or the first solution and the second solution may be added to the third solution with stirring and the resultant may be mixed. Alternatively, the first, second, and third solutions may each be added to a container and then mixed with stirring.

As a result of mixing the first, second, and third solutions, the first complex ions, the potassium ions, and the second complex ions react with each other, and a crystal of target first fluoride particles is precipitated. The thus precipitated crystal may be recovered through solid-liquid separation by filtration or the like. Further, a reducing agent such as a hydrogen peroxide solution may be added, and the crystal may be washed with a solvent such as ethanol, isopropyl alcohol, water, or acetone. In addition, a drying treatment may be performed as well. The drying treatment may be performed at usually 50° C. or higher, preferably 55° C. or higher, more preferably 60° C. or higher, but usually 110° C. or lower, preferably 105° C. or lower, more preferably 100° C. or lower. The drying time is not particularly limited as long as water adhering to the first fluoride particles may be removed, and it is, for example, about 10 hours.

At the time of mixing the first, second, and third solutions, it is preferred to take into consideration the difference between the composition of added phosphor raw materials and the composition of the resulting first fluoride particles and adjust the mixing ratio of the first, second, and third solutions as appropriate such that the first fluoride particles as a product have a target composition.

The method of producing the first fluoride particles may also include the particle size control step of performing a combination of treatments such as crushing, pulverization, and classification, after the drying treatment. By performing the particle size control step, a powder having a desired particle size may be obtained.

### Second Providing Step

In the second providing step, the second fluoride particles having the third composition are provided. The third composition may be a composition in which a ratio of a total number of moles of the alkali metal is 1 to 3 and a ratio of the number of moles of F is 4 to 6, with respect to 1 mole of Al. In one embodiment, the third composition may be a composition in which the ratio of a total number of moles of the alkali metal is 2 to 3 and the ratio of the number of moles of F is 5 to 6, with respect to 1 mole of Al.

The second fluoride particles may have a composition represented by the following Formula (IV) as the third composition:

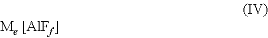

In Formula (IV), M represents an alkali metal and may contain at least K. Further, e and f may satisfy 2≤e≤3 and 5≤f≤6.

The second fluoride particles may have a composition represented by the following Formula (IVa) or (IVb), or may contain both of the following compositions:

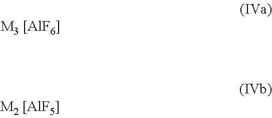

For example, from the viewpoint of the reactivity with the first fluoride particles, the specific surface area of the second fluoride particles may be 0.3 m²·g⁻¹ or more, preferably 1 m²·g⁻¹ or more, or 3 m²·g⁻¹ or more. An upper limit of the specific surface area of the second fluoride particles may be, for example, 30 m²·g⁻¹ or less. The specific surface area is measured by, for example, the BET method.

The second fluoride particles may be purchased, or produced by a known production method.

### First Heat Treatment Step

The first heat treatment step includes: mixing the thus provided first fluoride particles with second fluoride particles to obtain a mixture; and performing a first heat treatment of the thus obtained mixture in an inert gas atmosphere in a temperature range of 600° C. to 780° C. to obtain a first heat-treated product. This first heat-treated product contains a target fluoride phosphor.

The first fluoride particles and the second fluoride particles may be mixed by, for example, ordinary dry mixing. The dry mixing may be performed using, for example, a high-speed fluid mixer. As for a ratio of the first fluoride particles and the second fluoride particles in the resulting mixture, a ratio of the number of moles of the second fluoride particles with respect to a total number of moles of the first fluoride particles and the second fluoride particles may be, for example, higher than 0 but lower than 0.1, preferably lower than 0.05, or lower than 0.03. A lower limit of the ratio of the number of moles of the second fluoride particles may be preferably 0.003 or higher, or 0.005 or higher.

The heat treatment temperature in the first heat treatment step (hereinafter, also referred to as “first heat treatment temperature”) may be, for example, 600° C. or higher. The heat treatment temperature may be preferably 625° C. or higher, 650° C. or higher, or 675° C. or higher. When the heat treatment temperature is 600° C. or higher, the first fluoride particles may efficiently incorporate the second fluoride particles, and Si contained in the crystal structure of the first fluoride particles is partially substituted with Al, so that a fluoride phosphor having a high luminance may be obtained. Further, the heat treatment temperature in the first heat treatment step may be, for example, lower than 800° C. The heat treatment temperature may be preferably 780° C. or lower, 770° C. or lower, 760° C. or lower, or 750° C. or lower. When the heat treatment temperature is lower than 800° C., thermal decomposition of the fluoride particles may be effectively inhibited. In one embodiment, the first heat treatment temperature in the first heat treatment may be 650° C. to 750° C.

The heat treatment time in the first heat treatment step may be, for example, 1 hour to 40 hours, preferably 2 hours to 30 hours. When the heat treatment time is in this range, substitution of Si contained in the crystal structure of the first fluoride particles with Al proceeds more efficiently, so that a fluoride phosphor having a high luminance tends to be obtained. It is noted here that the “heat treatment time in the first heat treatment step” means a duration of maintaining the mixture of the first fluoride particles and the second fluoride particles at the first heat treatment temperature. The heating rate to the first heat treatment temperature in the first heat treatment step may be, for example, 1° C./min or higher.

In the first heat treatment step, the heat treatment of the mixture may be performed in an inert gas atmosphere. The “inert gas atmosphere” means, for example, an atmosphere which contains an inert gas, as a main component, such as a noble gas containing argon, helium or the like, or nitrogen. The main component in the inert gas atmosphere may be at least one selected from argon, helium, nitrogen, and the like, and may contain at least nitrogen. The concentration of an inert gas such as nitrogen gas in the inert gas atmosphere may be, for example, 70% by volume or higher, preferably 80% by volume or higher, 85% by volume or higher, 90% by volume or higher, or 95% by volume or higher. The inert gas may contain, as an unavoidable impurity, an active gas such as oxygen. The active gas concentration in the atmosphere used in the first heat treatment step may be 15% by volume or lower, preferably lower than 5% by volume, lower than 1% by volume, lower than 0.3% by volume, or lower than 0.1% by volume. The inert gas atmosphere does not have to contain an active gas such as oxygen. When the active gas concentration in the inert gas atmosphere is in the above-described range, oxidation of tetravalent Mn contained in the mixture may be sufficiently inhibited.

The pressure during the heat treatment in the first heat treatment step may be, for example, the atmospheric pressure (0.101 MPa). The pressure during the heat treatment may be higher than 0.101 MPa but 1 MPa or lower, or may be a reduced pressure that is lower than the atmospheric pressure (0.101 MPa).

### Washing Step

The method of producing a fluoride phosphor may further include the washing step of bringing the first heat-treated product obtained in the first heat treatment step into contact with a liquid medium. The washing step may include, for example, bringing the first heat-treated product into contact with the liquid medium, and performing solid-liquid separation of the first heat-treated product brought into contact with the liquid medium, and may further include performing a drying treatment of the first heat-treated product after the solid-liquid separation as required.

By bringing the first heat-treated product into contact with the liquid medium, for example, impurities generated in the first heat treatment step (e.g., an alkali metal fluoride such as potassium fluoride) may be removed at least partially. It is believed that, as a result, a change in the composition of the resulting fluoride phosphor may be inhibited, so that a reduction in the luminance, which is caused by a change in the composition, may be effectively inhibited.

Examples of the liquid medium brought into contact with the first heat-treated product include: lower alcohols, such as ethanol and isopropyl alcohol; ketone solvents, such as acetone; and water. From the viewpoint of removal of impurities, the liquid medium may contain at least water, and this water may be deionized water, distilled water, or purified water purified using a microfiltration membrane, an ultrafiltration membrane, a reverse osmosis membrane, or the like.

The liquid medium may also contain a reducing agent such as hydrogen peroxide. By incorporating a reducing agent into the liquid medium, even when the tetravalent Mn ion contained as an activator in the fluoride phosphor is oxidized by the first heat treatment, the oxidized tetravalent Mn ion is reduced by the reducing agent contained in the washing liquid, and the emission characteristics of the resulting fluoride phosphor may be further improved. When the liquid medium contains such a reducing agent, the content ratio thereof may be, for example, 0.01% by mass to 5% by mass, preferably 0.05% by mass to 1% by mass. The amount of the liquid medium used for contact with the first heat-treated product may be, for example, 2 times to 20 times of a total mass of the first heat-treated product.

The first heat-treated product and the liquid medium may be brought into contact with each other by mixing the first heat-treated product and the liquid medium and subsequently removing the liquid medium, or by passing the liquid medium through the first heat-treated product maintained in a funnel or the like. The contact time of the first heat-treated product and the liquid medium may be, for example, 1 hour to 20 hours. Further, the contact temperature of the first heat-treated product and the liquid medium may be, for example, 10° C. to 50° C.

The first heat-treated product brought into contact with the liquid medium may be subjected to a drying treatment. The drying temperature in the drying treatment may be, for example, 50° C. or higher, preferably 55° C. or higher, or 60° C. or higher, but 110° C. or lower, preferably 105° C. or lower, or 100° C. or lower. The drying time is the duration in which the liquid medium (e.g., water) adhering to the first heat-treated product through the contact may be evaporated at least partially, and it is, for example, about 10 hours.

### Second Heat Treatment Step

The method of producing a fluoride phosphor may further include the second heat treatment step of performing a second heat treatment of the first heat-treated product, which has been brought into contact with the liquid medium, in contact with a fluorine-containing substance at a second heat treatment temperature of 400° C. or higher so as to obtain a second heat-treated product. This second heat-treated product contains a target fluoride phosphor.

By heat-treating the first heat-treated product, which has been brought into contact with the liquid medium, in contact with a fluorine-containing compound, it is believed that fluorine atoms are supplied to fluorine atom-deficient regions in the crystal structure of the fluoride phosphor, and defects of the crystal structure are thereby further reduced. It is believed that, as a result, the luminance is further improved. In addition, the durability of the fluoride phosphor is believed to be further improved.

The fluorine-containing substance used in the second heat treatment step may be in any of a solid state, a liquid state, and a gaseous state at normal temperature. One example of the fluorine-containing substance in a solid state or a liquid state is NH₄F. Examples of the fluorine-containing substance in a gaseous state include F₂, CHF₃, CF₄, NH₄HF₂, HF, SiF₄, KrF₄, XeF₂, XeF₄, and NF₃, and the fluorine-containing substance in a gaseous state may be at least one selected from the group consisting of these substances, preferably at least one selected from the group consisting of F₂ and HF.

When the fluorine-containing substance is in a solid state or a liquid state at normal temperature, the first heat-treated product, which has been brought into contact with the liquid medium, and the fluorine-containing substance may be brought into a contact state by mixing. The first heat-treated product may be mixed with, for example, 1% by mass to 20% by mass, preferably 2% by mass to 10% by mass of the fluorine-containing substance in terms of the mass of fluorine atoms, with respect to a total of 100% by mass of the first heat-treated product and the fluorine-containing substance.

The temperature at which the first heat-treated product and the fluorine-containing substance are mixed may be, for example, in a range of room temperature (20° C.±5° C.) to a temperature lower than the second heat treatment temperature, or may be the second heat treatment temperature. Specifically, the temperature may be 20° C. or higher but lower than 400° C., or 400° C. or higher. When the temperature at which the first heat-treated product is brought into contact with the fluorine-containing substance that is in a solid state or a liquid state at normal temperature is 20° C. or higher but lower than 400° C., the first heat-treated product and the fluorine-containing substance are brought into contact with each other before performing the second heat treatment at a temperature of 400° C. or higher.

When the fluorine-containing substance is in a gaseous state, the first heat-treated product may be brought into contact therewith by arranging the first heat-treated product in an atmosphere containing the fluorine-containing substance. The atmosphere containing the fluorine-containing substance may include a noble gas or an inert gas such as nitrogen in addition to the fluorine-containing substance. In this case, the concentration of the fluorine-containing substance in the atmosphere may be, for example, 3% by volume to 35% by volume, preferably 5% by volume or higher, or 10% by volume or higher, but preferably 30% by volume or lower, or 25% by volume or lower.

The second heat treatment may be performed by maintaining the second heat treatment temperature over a prescribed period in a state where the first heat-treated product and the fluorine-containing substance are in contact with each other. The second heat treatment temperature may be, for example, 400° C. or higher, preferably higher than 400° C., 425° C. or higher, 450° C. or higher, or 480° C. or higher. An upper limit of the second heat treatment temperature may be, for example, lower than 600° C., preferably 580° C. or lower, 550° C. or lower, or 520° C. or lower. The second heat treatment temperature may be lower than the first heat treatment temperature.

When the second heat treatment temperature is equal to or higher than the above-described lower limit value, fluorine atoms are sufficiently supplied to the first heat-treated product, so that the luminance of the resulting fluoride phosphor tends to be further improved. Further, when the second heat treatment temperature is equal to or lower than the above-described upper limit value, decomposition of the resulting fluoride phosphor is more effectively inhibited, so that the luminance of the resulting fluoride phosphor tends to be further improved.

The heat treatment time in the second heat treatment, i.e. duration of maintaining the second heat treatment temperature, may be, for example, 1 hour to 40 hours, preferably 2 hours or longer, or 3 hours or longer, but preferably 30 hours or shorter, 10 hours or shorter, or 8 hours or shorter. When the heat treatment time at the second heat treatment temperature is in this range, fluorine atoms may be sufficiently supplied to the first heat-treated product which has been brought into contact with the liquid medium. As a result, the crystal structure of the resulting fluoride phosphor is further stabilized, so that a fluoride phosphor having a high luminance tends to be obtained.

The heat treatment time at the second heat treatment temperature may be equal to or longer than the heat treatment time at the first heat treatment temperature. In other words, the heat treatment time at the second heat treatment temperature may be one or more times of the heat treatment time at the first heat treatment temperature. This allows fluorine atoms to be sufficiently supplied to the first heat-treated product which has been brought into contact with the liquid medium, so that the luminance of the resulting fluoride phosphor tends to be further improved.

The pressure in the second heat treatment step may be, for example, the atmospheric pressure (0.101 MPa), higher than the atmospheric pressure but 5 MPa or lower, or higher than the atmospheric pressure but 1 MPa or lower.

The method of producing a fluoride phosphor may also include the particle size control step of performing a combination of treatments, such as crushing, pulverization, and classification, for the second heat-treated product obtained after the second heat treatment step. By performing the particle size control step, a powder having a desired particle size may be obtained.

Details of the fluoride phosphor obtained by the method of producing a fluoride phosphor are the same as those of the above-described fluoride phosphor. In other words, the resulting fluoride phosphor may have a composition represented by the following Formula (I):

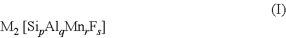

In Formula (I), M represents an alkali metal and may contain at least K; and p, q, r, and s satisfy 0.9≤p+q+r≤1.1, 0<q≤0.1, 0<r≤0.2, and 5.9≤s≤6.1.

### Light Emitting Device

The light emitting device includes: a first light emitting material containing the above-described fluoride phosphor; and a light emitting element having an emission peak wavelength in a wavelength range of 380 nm to 485 nm. The light emitting device may further include other constituent members as required.

One example of the light emitting device will now be described referring to the drawings. FIG. 2 is a schematic cross-sectional view that illustrates one example of the light emitting device according to the present embodiment. This light emitting device is an example of a surface-mount-type light emitting device. A light emitting device 100 includes: a light emitting element 10 which emits light having an emission peak wavelength in the short-wavelength side of visible light (e.g., in a range of 380 nm to 485 nm); and a molded body 40 in which the light emitting element 10 is arranged. The molded body 40 includes a first lead 20 and a second lead 30, and is integrally molded with a thermoplastic resin or a thermosetting resin. The molded body 40 forms a recess having a bottom surface and a side surface, and the light emitting element 10 is arranged on the bottom surface of this recess. The light emitting element 10 has a pair of positive and negative electrodes, which are each electrically connected to the first lead 20 or the second lead 30 via a wire 60. The light emitting element 10 is sealed by a wavelength conversion member 50. The wavelength conversion member 50 contains a light emitting material 70 which contains a fluoride phosphor converting the wavelength of the light emitted from the light emitting element 10. The light emitting material 70 may contain a first light emitting material which contains the above-described fluoride phosphor, and a second light emitting material which, upon receiving an excitation light from the light emitting element 10, emits light having an emission peak wavelength in a wavelength range different from that of the fluoride phosphor.

The wavelength conversion member may contain a resin and a light emitting material. Examples of the resin constituting the wavelength conversion member include silicone resins and epoxy resins. The wavelength conversion member may further contain a light diffusing material in addition to the resin and the phosphor. By incorporating a light diffusing material, the directivity of light emitted from the light emitting element is reduced, so that the viewing angle may be increased. Examples of the light diffusing material include silicon oxide, titanium oxide, zinc oxide, zirconium oxide, and aluminum oxide.

The light emitting element emits light having an emission peak wavelength in a wavelength range of 380 nm to 485 nm, which is a short wavelength region of visible light. The light emitting element may be an excitation light source that excites the fluoride phosphor. The light emitting element has an emission peak wavelength preferably in a range of 380 nm to 480 nm, more preferably in a range of 410 nm to 480 nm. As the light emitting element is used as an excitation light source, it is preferred to use a semiconductor light emitting element. By using a semiconductor light emitting element as an excitation light source, a light emitting device which not only has high efficiency and high input-output linearity but also is strong and stable against mechanical impact may be obtained. As the semiconductor light emitting element, for example, a semiconductor light emitting element containing a nitride-based semiconductor may be used. In the emission spectrum of the light emitting element, the half-value width of an emission peak is preferably, for example, 30 nm or less.

The light emitting device is configured to include the first light emitting material containing the fluoride phosphor. Details of the fluoride phosphor contained in the light emitting device are as described above. The fluoride phosphor is contained in, for example, the wavelength conversion member covering the excitation light source. In the light emitting device in which the excitation light source is covered by the wavelength conversion member containing the fluoride phosphor, light emitted from the excitation light source is partially absorbed by the fluoride phosphor and radiated as red light. By using an excitation light source that emits light having an emission peak wavelength in a range of 380 nm to 485 nm, the radiated light may be utilized more effectively and the loss of the light emitted from the light emitting device may be reduced, so that a highly efficient light emitting device may be provided.

The light emitting device preferably further includes the second light emitting material containing a light emitting material other than the fluoride phosphor, in addition to the first light emitting material containing the fluoride phosphor. The light emitting material other than the fluoride phosphor may be any material as long as it absorbs light emitted from a light source and converts this light into a light having a wavelength different from the light emitted by the fluoride phosphor. The light emitting material contains a phosphor, a quantum dot, and the like. The second light emitting material may be contained in, for example, the wavelength conversion member in the same manner as the first light emitting material.

The second light emitting material may have an emission peak wavelength in a wavelength range of 495 nm to 590 nm, and may be preferably at least one selected from the group consisting of a β sialon phosphor, a halosilicate phosphor, a silicate phosphor, a rare earth aluminate phosphor, a perovskite light emitting material, and a nitride phosphor. The β sialon phosphor may have a composition represented by, for example, the below-described Formula (IIa). The halosilicate phosphor may have a composition represented by, for example, the below-described Formula (IIb). The silicate phosphor may have a composition represented by, for example, the below-described Formula (IIc). The rare earth aluminate phosphor may have a composition represented by the below-described Formula (IId). The perovskite light emitting material may have a composition represented by, for example, the below-described Formula (IIe), and may be a quantum dot. The nitride phosphor may have a composition represented by, for example, the below-described Formula (IIf), (IIg), or (IIh).

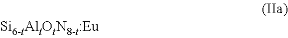

wherein, t represents a number satisfying 0<t≤4.2.

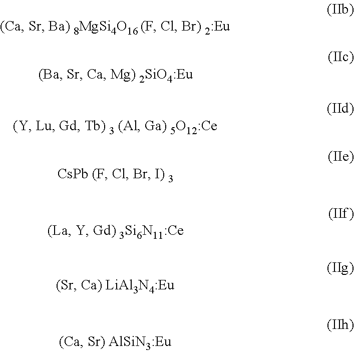

In the present specification, plural elements listed separately with commas (,) in a formula representing the composition of a phosphor or a light emitting material mean that at least one of the plural elements is contained in the composition. Further, in a formula representing the composition of a phosphor, the part preceding a colon (:) represents a host crystal, and the part following the colon (:) represents an activation element.

### EXAMPLES

The present invention will now be described more concretely by way of Examples; however, the present invention is not limited to the below-described Examples.

### Production Example 1: Production of First Fluoride Particles

A first solution was prepared by weighing 7,029 g of KHF₂ and dissolving this KHF₂ into 38.5 L of a 55%-by-mass aqueous HF solution. Further, a second solution was prepared by weighing 1,049.7 g of K₂MnF₆ and dissolving this K₂MnF₆ into 12.0 L of a 55%-by-mass aqueous HF solution. Subsequently, a third solution was obtained by preparing 15.5 L of an aqueous solution containing 40% by mass of H₂SiF₆. Next, while stirring the first solution at room temperature, the second solution and the third solution were added thereto dropwise over a period of about 20 hours. After the completion of this dropwise addition, 400 ml of a 35% hydrogen peroxide solution was added and the resultant was washed with pure water, after which the resulting precipitate was solid-liquid separated, washed with ethanol, and then dried at 90° C. for 10 hours, whereby first fluoride particles of Production Example 1 were produced. The thus obtained first fluoride particles had a composition represented by K₂ [Si_{0.949}Mn_{0.051}F₆].

### Example 1

The first fluoride particles produced in Production Example 1, which had a composition represented by K₂ [Si_{0.949}Mn_{0.051}F₆], and second fluoride particles having a composition represented by K₃[AlF₆] were weighed in amounts of 2,200 g and 7.76 g, respectively, and mixed such that the ratio of the number of moles of the second fluoride particles was 0.003 with respect to a total number of moles of the first fluoride particles and the second fluoride particles, whereby a mixture of the first fluoride particles and the second fluoride particles was prepared. In an inert gas atmosphere having a nitrogen gas concentration of 100% by volume, a first heat treatment was performed on the mixture of the first fluoride particles and the second fluoride particles at a temperature of 700° C. for a heat treatment time of 5 hours to obtain a first heat-treated product. The thus obtained first heat-treated product was thoroughly washed with a washing solution containing 1% by mass of hydrogen peroxide. In an atmosphere having a fluorine gas (F₂) concentration of 20% by volume and a nitrogen gas concentration of 80% by volume, a second heat treatment was performed on the thus washed first heat-treated product in contact with fluorine gas at a temperature of 500° C. for a heat treatment time of 5 hours, whereby a fluoride phosphor of Example 1 was produced. It is noted here that the heat treatment time in each of the first heat treatment and the second heat treatment means an elapsed time until the termination of heating after the temperature reached the prescribed heat treatment temperature. The fluoride phosphor of Example 1 had a composition represented by K₂ [Si_{0.948}Al_{0.002}Mn_{0.050}F_{5.998}].

### Comparative Example 1

A fluoride phosphor was produced under the same conditions as in Example 1, except that the first fluoride particles produced in Production Example 1, which had a composition represented by K₂ [Si_{0.949}Mn_{0.051}F₆], were used alone without being mixed with the second fluoride particles. The thus obtained fluoride phosphor of Comparative Example 1 had a composition represented by K₂ [Si_{0.950}Mn_{0.050}F₆].

### Example 2

A fluoride phosphor was produced under the same conditions as in Example 1, except that the mass of the second fluoride particles was changed to 15.57 g such that the ratio of the number of moles of the second fluoride particles was 0.006 with respect to a total number of moles of the first fluoride particles and the second fluoride particles. The thus obtained fluoride phosphor of Example 2 had a composition represented by K₂ [Si_{0.946}Al_{0.005}Mn_{0.049}F_{5.995}].

### Example 3

A fluoride phosphor was produced under the same conditions as in Example 1, except that the mass of the second fluoride particles was changed to 23.43 g such that the ratio of the number of moles of the second fluoride particles was 0.009 with respect to a total number of moles of the first fluoride particles and the second fluoride particles. The thus obtained fluoride phosphor of Example 3 had a composition represented by K₂ [Si_{0.942}Al_{0.008}Mn_{0.050}F_{5.992}].

### Example 4

A fluoride phosphor was produced under the same conditions as in Example 1, except that the mass of the second fluoride particles was changed to 39.28 g such that the ratio of the number of moles of the second fluoride particles was 0.015 with respect to a total number of moles of the first fluoride particles and the second fluoride particles. The thus obtained fluoride phosphor of Example 4 had a composition represented by K₂ [Si_{0.939}Al_{0.014}Mn_{0.047}F_{5.986}].

### Example 5

A fluoride phosphor was produced under the same conditions as in Example 1, except that the mass of the second fluoride particles was changed to 55.33 g such that the ratio of the number of moles of the second fluoride particles was 0.021 with respect to a total number of moles of the first fluoride particles and the second fluoride particles. The thus obtained fluoride phosphor of Example 5 had a composition represented by K₂ [Si_{0.933}Al_{0.018}Mn_{0.049}F_{5.982}].

### <Evaluation>

### Chromaticity Coordinates

Using a spectrofluorometer (product name: QE-2000, manufactured by Otsuka Electronics Co., Ltd.), the above-obtained fluoride phosphors of Examples and Comparative Example were each irradiated with an excitation light having a peak wavelength of 450 nm to measure the emission spectrum of each fluoride phosphor at room temperature. From the data of the thus obtained emission spectrum of each fluoride phosphor of Examples and Comparative Example, the xy chromaticity coordinates in the CIE (Commission internationale de l′éclairage) 1931 color system were determined. The results thereof are shown in Table 1.

### Relative Luminance

From the data of the emission spectrum measured for each fluoride phosphor of Examples and Comparative Example, the emission luminance was determined for the fluoride phosphors of Examples 1 to 5 in terms of relative luminance, taking the luminance of the fluoride phosphor of Comparative Example 1 as 100%. The results thereof are shown in Table 1.

### Composition

For each of the above-obtained fluoride phosphors of Examples and Comparative Example, the composition was analyzed by inductively-coupled plasma atomic emission spectrometry (ICP-AES), and the molar content ratio of each element was calculated, assuming that the amount of potassium contained in the composition was 2 moles. The results thereof are shown in Table 1.

### Angle of Repose

For each of the above-obtained fluoride phosphors of Examples and Comparative Example, the angle of repose was measured using an A.B.D powder property analyzer (product name: ABD-100, manufactured by Tsutsui Scientific Instruments Co., Ltd.), and the angle of repose was determined from an average value of two measurements. The results thereof are shown in Table 1.

### Dispersity

For each of the above-obtained fluoride phosphors of Examples and Comparative Example, the dispersity was measured three times using an A.B.D powder property analyzer (product name: ABD-100, manufactured by Tsutsui Scientific Instruments Co., Ltd.), and an arithmetic mean of the measured values was defined as the dispersity. The results thereof are shown in Table 1.

### Bulk Density

For each of the above-obtained fluoride phosphors of Examples and Comparative Example, the bulk density was measured three times in the same manner as the dispersity using an A.B.D powder property analyzer (product name: ABD-100, manufactured by Tsutsui Scientific Instruments Co., Ltd.), and an arithmetic mean of the measured values was defined as the bulk density. The results thereof are shown in Table 1.

### Lattice Constant

The above-obtained fluoride phosphors of Examples and Comparative Example were each mixed with a Si standard sample at a ratio of 1:1, and the X-ray diffraction pattern was measured using a sample horizontal-type multi-purpose X-ray diffractometer (product name: ULTIMA IV, manufactured by Rigaku Corporation; X-ray source: CuKa radiation (λ=0.15418 nm, tube voltage=40 kV, tube current=40 mA)) under the following measurement conditions: angle=10° to 70°, scanning width=0.02°, and scanning speed=20°/min. From the thus obtained X-ray diffraction pattern of each fluoride phosphor of Examples 1 to 5 and Comparative Example 1, the lattice constant was calculated using an integrated X-ray powder diffraction analysis software (PDXL2) and the card data (K₂SiF₆: 01-081-2264, Si: 00-027-1402) of ICDD (International Center for Diffraction Data). The results thereof are shown in Table 1.

TABLE 1

| | | | Relative | | | Angle of | | Bulk | Lattice |
|---|---|---|---|---|---|---|---|---|---|
| | Chromaticity coordinates | | luminance | Mn ratio | Al ratio | repose | Dispersity | density | constant |
| | x | y | (%) | (r) | (q) | (°) | (%) | (g · cm⁻³) | (nm) |
| Comparative | 0.694 | 0.306 | 100.0 | 0.050 | 0.000 | 61 | 1.1 | 0.99 | 0.8137 |
| Example 1 | | | | | | | | | |
| Example 1 | 0.695 | 0.305 | 102.0 | 0.050 | 0.002 | 58 | 2.4 | 1.06 | 0.8139 |
| Example 2 | 0.694 | 0.306 | 103.7 | 0.049 | 0.005 | 55 | 4.2 | 1.08 | 0.8142 |
| Example 3 | 0.694 | 0.306 | 104.0 | 0.050 | 0.008 | 42 | 27.6 | 1.20 | 0.8143 |
| Example 4 | 0.694 | 0.306 | 102.6 | 0.047 | 0.014 | 43 | 32.0 | 1.21 | 0.8150 |
| Example 5 | 0.694 | 0.305 | 101.8 | 0.049 | 0.018 | 41 | 32.6 | 1.23 | 0.8149 |

As shown in Table 1, the fluoride phosphors of Examples had a higher luminance than the fluoride phosphor of Comparative Example. This is presumed to be an effect of reduced F defects, which is attributed to partial substitution of Si with Al in the crystal structures of the fluoride phosphors of Examples. Further, in the fluoride phosphors of Examples, the lattice constant increased as the amount of Al was increased. This is believed to suggest that Si in the respective crystal structures was substituted with Al.

### Infrared Spectrometry: FT-IR Evaluation

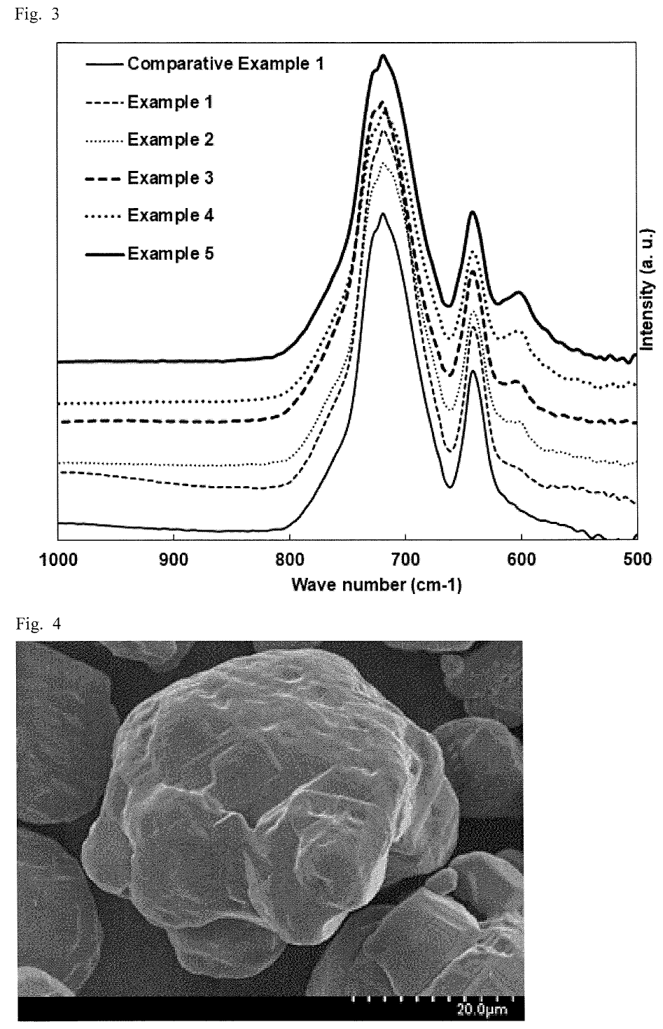

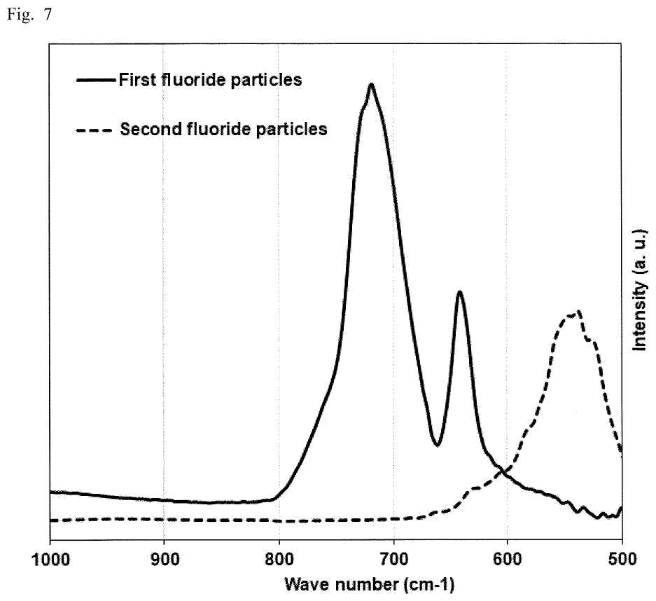

For each of the above-obtained fluoride phosphors of Examples and Comparative Example, an infrared absorption spectrum was measured by an attenuated total reflection (ATR) method using a Fourier transform infrared spectrometer (FT-IR-6200, manufactured by JASCO Corporation). FIG. 3 shows partially enlarged views of the thus obtained infrared absorption spectra of the fluoride phosphors of Examples 1 to 5 and Comparative Example 1. In addition, for reference, FIG. 7 shows the infrared absorption spectrum of the first fluoride particles and that of the second fluoride particles.

As shown in FIG. 3, the fluoride phosphors of Examples exhibited a characteristic absorption peak in a wavenumber range of 590 cm⁻¹ to 610 cm⁻¹. On the other hand, such an absorption peak was not observed for the fluoride phosphor of Comparative Example. This is believed to suggest that Si was partially substituted with Al in the crystal structures of the fluoride phosphors of Examples.

### SEM Image

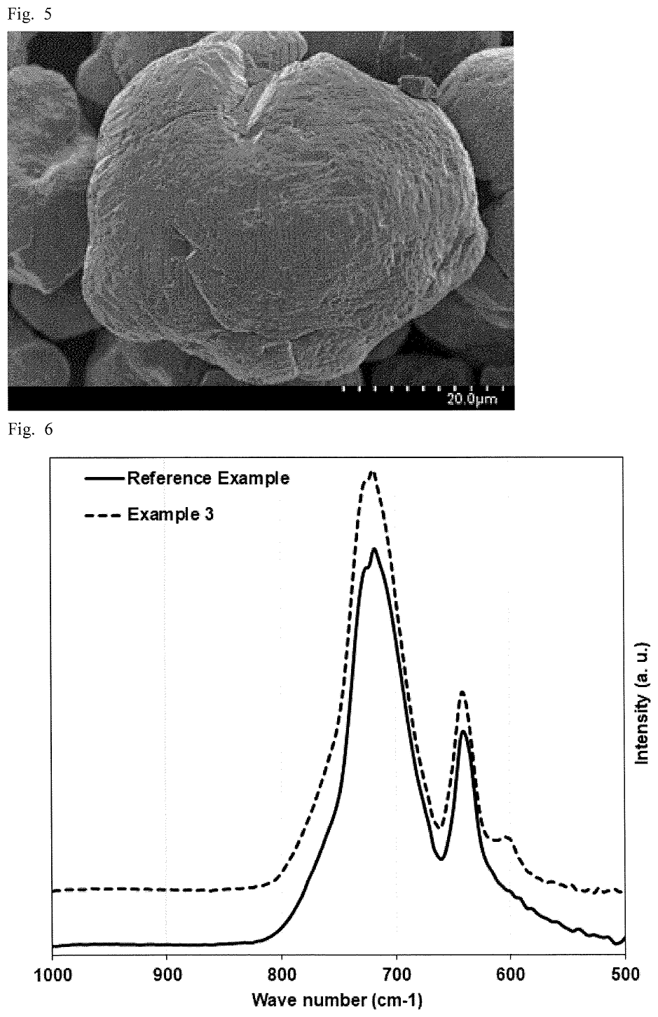

SEM images of the fluoride phosphors were obtained using a scanning electron microscope (SEM). FIG. 4 shows an SEM image of the fluoride phosphor of Comparative Example 1, and FIG. 5 shows an SEM image of the fluoride phosphor of Example 3.

As compared to the fluoride phosphor of Comparative Example 1 shown in FIG. 4, fine steps are formed on the particle surface of the fluoride phosphor of Example 3 shown in FIG. 5. It is presumed that these fine steps made aggregation of particles unlikely to occur, and the angle of repose was thereby reduced. Due to such a particle surface state, as shown in Table 1, the fluoride phosphor of Examples had a higher dispersity and a higher bulk density than the fluoride phosphor of Comparative Example and, in the fluoride phosphors of Examples 1 to 5, the dispersity and the bulk density increased as the amount of Al was increased.

### Reference Example

Referring to Japanese Laid-Open Patent Publication No. 2010-254933, a fluoride phosphor of Reference Example was produced as follows. A solution 1 was prepared by weighing 4.74 g of K₂MnF₆, and adding and dissolving this K₂MnF₆ into a mixed solution of 60.8 g of a 40%-by-mass aqueous H₂SiF₆ solution, 190 g of a 55%-by-mass aqueous HF solution, and 30 g of deionized water (DIW). In addition, a solution 2 was prepared by weighing 21.42 g of KHF₂ and 20.34 g of K₃AlF₆, and dissolving them in 205 g of a 55%-by-mass aqueous HF solution. While stirring this solution 2 at room temperature, the solution 1 was added thereto dropwise over a period of about 2 minutes. The resulting precipitate was solid-liquid separated, washed with ethanol, and then dried at 90° C. for 10 hours, whereby a fluoride phosphor of Reference Example was produced.

For the thus obtained fluoride phosphor of Reference Example, in the same manner as described above, the composition was analyzed, and the X-ray diffraction pattern and the infrared absorption spectrum were measured. The results thereof are shown in Table 2 and FIG. 6 along with the analysis results of the fluoride phosphor of Example 3. The fluoride phosphor of Reference Example had a composition represented by K₂ [Si_{0.947}Al_{0.009}Mn_{0.044}F_{5.991}].

TABLE 2

| | | | Lattice |
|---|---|---|---|
| | Mn ratio | Al ratio | constant |
| | (r) | (q) | (nm) |
| Reference | 0.044 | 0.009 | 0.8137 |
| Example | | | |
| Example 3 | 0.050 | 0.008 | 0.8143 |

The fluoride phosphor of Reference Example had substantially the same lattice constant as that of the fluoride phosphor of Comparative Example 1, and was not observed with a characteristic infrared absorption peak. From these results, it was suggested that Si was not substituted with Al in the crystal structures of the fluoride phosphor of Reference Example.

### Example 10: Production of Light Emitting Devices

The above-obtained fluoride phosphors of Example 3 and Comparative Example 1 were each used as a first light emitting material. As a second light emitting material, a β sialon phosphor having a composition represented by Si_{5.81}Al_{0.19}O_{0.19}N_{7.81}: Eu and exhibiting an emission peak wavelength at about 540 nm was used. A phosphor 70, which was obtained by blending the first light emitting material and the second light emitting material such that the phosphor had x and y values of 0.280 and about 0.270, respectively, in the chromaticity coordinates of the CIE 1931 color system, was mixed with a silicone resin to obtain a resin composition. Subsequently, a molded body 40 having a recess as shown in FIG. 2 was prepared and, in the bottom of the recess, a light emitting element 10 which had an emission peak wavelength of 451 nm and was made of a gallium nitride-based compound semiconductor was arranged on a first lead 20, after which the electrodes of the light emitting element 10 were each connected with the first lead 20 or a second lead 30 via a wire 60. Thereafter, using a syringe, the resin composition was injected into the recess of the molded body 40 in such a manner to cover the light emitting element 10, and this resin composition was cured to form a wavelength conversion member, whereby a light emitting device was produced.

### Relative Luminous Flux

Using a total luminous flux analyzer equipped with an integrating sphere, the luminous flux of each of the thus produced light emitting devices containing the fluoride phosphor of Example 3 or Comparative Example 1 was measured. The luminous flux of the light emitting device containing the fluoride phosphor of Example 3 was determined in terms of relative luminous flux, taking the luminous flux of the light emitting device containing the fluoride phosphor of Comparative Example 1 as 100%. The result thereof is shown in Table 3.

TABLE 3

| | | Phosphor | | | | | Relative |
|---|---|---|---|---|---|---|---|
| Phosphor | | mass ratio to | Phosphor mass ratio (%) | | | | luminous |
| Second | First | 100 mass part | Second | First | Chromaticity coordinates | | flux |
| phosphor | phosphor | of resin (%) | phosphor | phosphor | x | y | (%) |
| β sialon | Comparative | 34.0 | 38.1 | 61.9 | 0.280 | 0.270 | 100.0 |
| | Example 1 | | | | | | |
| β sialon | Example 3 | 34.6 | 38.3 | 61.7 | 0.280 | 0.270 | 100.5 |

As shown in Table 2, in the light emitting device containing the fluoride phosphor of Example 3, the relative luminous flux was improved by the use of the fluoride phosphor having a high emission luminance, as compared to the light emitting device containing the fluoride phosphor Comparative Example 1.

A fluoride phosphor obtained by the production method of the present disclosure may be used particularly in light emitting devices in which a light emitting diode is used as an excitation light source, and thereby suitably applied to, for example, light sources for illumination, LED displays, liquid-crystal backlight applications and the like, as well as signals, illuminated switches, various sensors and indicators, and small strobes.

The disclosures of Japanese Patent Application No. 2020-212532 (filing date: Dec. 22, 2020), Japanese Patent Application No. 2021-112539 (filing date: Jul. 7, 2021), and Japanese Patent Application No. 2021-144746 (filing date: Sep. 6, 2021) are hereby incorporated by reference in their entirety. All the documents, patent applications, and technical standards that are described in the present specification are hereby incorporated by reference to the same extent as if each individual document, patent application, or technical standard is concretely and individually described to be incorporated by reference.

1. A fluoride phosphor, having a first composition which comprises an alkali metal containing K, Si, Al, Mn, and F, wherein
in the first composition, when a total number of moles of the alkali metal is 2: a total number of moles of Si, Al, and Mn is 0.9 or more and 1.1 or less; a number of moles of Al is more than 0 and 0.1 or less; a number of moles of Mn is more than 0 and 0.2 or less; and a number of moles of F is 5.9 or more and 6.1 or less, and
the fluoride phosphor has a crystal structure of cubic system, and a lattice constant of not less than 0.8138 nm.

2. The fluoride phosphor according to claim 1, wherein the number of moles of Al in the first composition is more than 0 but 0.03 or less.

3. The fluoride phosphor according to claim 1 or 2, wherein the lattice constant is not less than 0.8140 nm.

4. The fluoride phosphor according to any one of claims 1 to 3, wherein a powder composed of the fluoride phosphor has an angle of repose of 60° or smaller.

5. The fluoride phosphor according to any one of claims 1 to 4, wherein the fluoride phosphor has an absorption peak in a wavenumber range of 590 cm⁻¹ to 610 cm⁻¹ in an infrared absorption spectrum.

6. The fluoride phosphor according to any one of claims 1 to 5, wherein the powder composed of the fluoride phosphor has a dispersity of 2.0% or more.

7. The fluoride phosphor according to any one of claims 1 to 6, wherein the powder composed of the fluoride phosphor has a bulk density of 1.00 g·cm⁻³ or higher.

8. The fluoride phosphor according to any one of claims 1 to 7, wherein the fluoride phosphor has a composition represented by the following Formula (I): 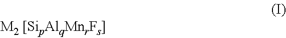
wherein, M represents an alkali metal and contains at least K; and p, q, r, and s satisfy 0.9≤p+q+r≤1.1, 0<q<0.1, 0<r≤0.2, and 5.9≤s≤6.1.

9. A light emitting device, comprising:
a first light emitting material comprising the fluoride phosphor according to any one of claims 1 to 8; and
a light emitting element having an emission peak wavelength in a wavelength range of 380 nm to 485 nm.

10. The light emitting device according to claim 9, further comprising a second light emitting material having an emission peak wavelength in a wavelength range of 495 nm to 590 nm.

11. The light emitting device according to claim 10, wherein the second light emitting material is at least one selected from the group consisting of a β sialon phosphor, a halosilicate phosphor, a silicate phosphor, a rare earth aluminate phosphor, a perovskite light emitting material, and a nitride phosphor.

12. The light emitting device according to claim 10 or 11, wherein the second light emitting material comprises at least one selected from the group consisting of light emitting materials having a composition represented by any one of the following Formulae (IIa) to (IIh): 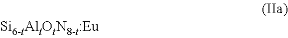
wherein, t represents a number satisfying 0<t≤4.2;

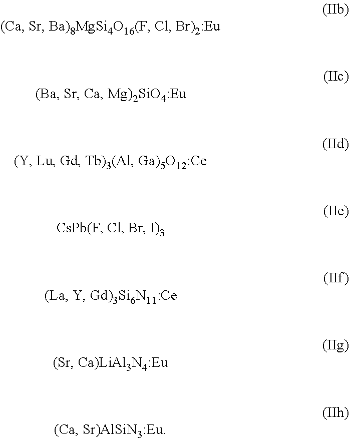

13. A method of producing a fluoride phosphor, the method comprising:
providing first fluoride particles having a second composition which comprises an alkali metal containing K, Si, Mn, and F, and in which, when a total number of moles of the alkali metal is 2: a total number of moles of Si and Mn is 0.9 or more and 1.1 or less; a number of moles of Mn is more than 0 and 0.2 or less; and a number of moles of F is 5.9 or more and 6.1 or less;
providing second fluoride particles having a third composition which comprises an alkali metal containing K, Al, and F, and in which, when a number of moles of Al is 1: a total number of moles of the alkali metal is 2 or more and 3 or less; and a number of moles of F is 5 or more and 6 or less; and
obtaining a first heat-treated product by performing a first heat treatment of a mixture of the first fluoride particles and the second fluoride particles in an inert gas atmosphere at a temperature of 600° C. or higher and 780° C. or lower.

14. The method of producing a fluoride phosphor according to claim 13, the method further comprising bringing the first heat-treated product obtained by the first heat treatment into contact with a liquid medium.

15. The method of producing a fluoride phosphor according to claim 14, wherein, in the process of bringing the first heat-treated product into contact with the liquid medium, the liquid medium comprises water.

16. The method of producing a fluoride phosphor according to claim 14 or 15, wherein, in the process of bringing the first heat-treated product into contact with the liquid medium, the liquid medium comprises a reducing agent.

17. The method of producing a fluoride phosphor according to any one of claims 14 to 16, the method further comprising, after bringing the first heat-treated product into contact with the liquid medium, obtaining a second heat-treated product by bringing the first heat-treated product into contact with a fluorine-containing substance and performing a second heat treatment at a temperature of 400° C. or higher.

18. The method of producing a fluoride phosphor according to claim 17, wherein, in the process of obtaining the second heat-treated product, the fluorine-containing substance is at least one selected from the group consisting of F₂, CHF₃, CF₄, NH₄HF₂, HF, SiF₄, KrF₂, XeF₂, XeF₄, and NF₃.

19. The method of producing a fluoride phosphor according to claim 17 or 18, wherein the heat treatment time in the second heat treatment is one or more times of the heat treatment time in the first heat treatment.

20. The method of producing a fluoride phosphor according to any one of claims 17 to 19, wherein the temperature in the second heat treatment is lower than the temperature of the first heat treatment.

21. The method of producing a fluoride phosphor according to any one of claims 13 to 20, wherein the fluoride phosphor obtained by the method has a composition represented by the following Formula (I): 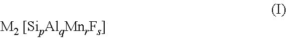
wherein, M represents an alkali metal and contains at least K; and p, q, r, and s satisfy 0.9≤p+q+r≤1.1, 0<q≤0.1, 0<r≤0.2, and 5.9≤s≤6.1.

22. The method of producing a fluoride phosphor according to any one of claims 13 to 21, wherein, in the process of providing the first fluoride particles, the first fluoride particles have a composition represented by the following Formula (III): 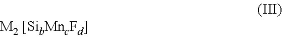
wherein, M represents an alkali metal and contains at least K; and b, c, and d satisfy 0.9≤b+c≤1.1, 0<c≤0.2, and 5.9≤d≤6.1.

23. The method of producing a fluoride phosphor according to any one of claims 13 to 22, wherein, in the process of providing the second fluoride particles, the second fluoride particles have a composition represented by the following Formula (IV): 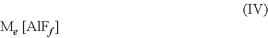
wherein, M represents an alkali metal and contains at least K; and e and f satisfy 2≤e≤3 and 5≤f≤6.

24. The method of producing a fluoride phosphor according to any one of claims 13 to 23, wherein, in the process of obtaining the first heat-treated product by performing the first heat treatment, the inert gas atmosphere comprises nitrogen.

25. The method of producing a fluoride phosphor according to any one of claims 13 to 24, wherein the first heat treatment is performed in a temperature range of 650° C. or higher and 750° C. or lower.
